(19) United States
(12) Patent Application Publication
(10) Pub. No.: US 2018/0087157 A1
(43) Pub. Date: Mar. 29, 2018

(54) MULTI-COMPOSITION FIBER WITH REFRACTORY ADDITIVE(S) AND METHOD OF MAKING

(71) Applicant: FREE FORM FIBERS, LLC, Saratoga Springs, NY (US)

(72) Inventors: Shay L. HARRISON, East Schodack, NY (US); Joseph PEGNA, Saratoga Springs, NY (US); Erik G. VAALER, Redwood City, CA (US); John L. SCHNEITER, Cohoes, NY (US); Ram K. GODUGUCHINTA, Ballston Lake, NY (US); Kirk L. WILLIAMS, Saratoga Springs, NY (US)

(73) Assignee: FREE FORM FIBERS, LLC, Saratoga Springs, NY (US)

(21) Appl. No.: 15/718,199

(22) Filed: Sep. 28, 2017

Related U.S. Application Data
(60) Provisional application No. 62/400,709, filed on Sep. 28, 2016.

(51) Int. Cl. C23C 16/48; C23C 16/42; C23C 16/40; C23C 16/34; C23C 16/32

(52) U.S. Cl. CPC C23C 16/483; C23C 16/42; C23C 16/32; C23C 16/34; C23C 16/40

(57) ABSTRACT

Multi-composition fibers with one or more refractory additives, and methods of making the fibers, are provided. The method(s) includes providing a precursor-laden environment, and promoting fiber growth using laser heating. The precursor-laden environment includes a primary precursor material and a refractory precursor material. The multi-composition fiber may include a primary fiber material, and a refractory material substantially homogeneously intermixed with the primary fiber material.

### CROSS-REFERENCE TO RELATED APPLICATION

This application claims the benefit of U.S. provisional patent application Ser. No. 62/400,709, filed Sep. 28, 2016, entitled “Multi-Composition Fiber with Refractory Additives and Method of Making”, which is hereby incorporated herein by reference in its entirety.

### BACKGROUND

The present invention relates generally to the field of fibers for reinforcing materials and more specifically to the field of fibers having material additives.

In a wide variety of applications, fiber composite materials, incorporating fibers into a surrounding material matrix, provide higher structural performance than traditional, bulk (i.e., non-fiber) materials. Unfortunately, however, conventionally-produced, single-composition fibers often suffer from poorer oxidation resistance than their bulk material counterparts owing to the ease with which additives may be incorporated in the bulk materials.

### SUMMARY

Although the addition of refractory materials increases the oxidation resistance of, for instance, bulk silicon carbide, conventional methods of silicon carbide fiber production are unable to incorporate such additives. Opportunities exist, therefore, to improve fiber oxidation resistance performance by providing a multi-composition fiber with refractory additives.

The opportunities described above are addressed, in one aspect of the present invention, by a method of making a multi-composition fiber, the method comprising acts of providing a precursor laden environment and promoting fiber growth using laser heating, the precursor laden environment comprising a primary precursor material and a refractory precursor material. In another aspect of the present invention, an article of manufacture is a multi-composition fiber comprising a primary fiber material and a refractory fiber material substantially homogenously intermixed with the primary fiber material.

Additional features and advantages are realized through the techniques of the present invention. Other embodiments and aspects of the invention are described in detail herein and are considered a part of the claimed invention.

### DRAWINGS

These and other features, aspects, and advantages of the present invention will become better understood when the following detailed description is read with reference to the accompanying drawings in which like characters represent like parts throughout the drawings, and wherein:

FIG. 1 is a schematic representation of a single-fiber reactor, showing a seed fiber substrate, a reactor cube into which precursor gases are delivered, a focused laser beam impinging on the seed fiber, and reactor windows that are transparent to the incoming laser beam wavelength and allow for, for instance, video monitoring of the process, in accordance with one or more aspects of the present invention;

FIG. 2 is a schematic view showing how LCVD can be massively parallelized by a multiplication of the laser beams, in accordance with one or more aspects of the present invention;

FIG. 3 depicts an example of parallel LCVD growth of carbon fibers, in accordance with one or more aspects of the present invention;

FIG. 4A is a simplified schematic of components of an LCVD system facilitating fabrication of a multi-composition fiber with refractory additive(s), in accordance with one or more aspects of the present invention;

FIG. 4B depicts one embodiment of a process for fabricating a multi-composition fiber with refractory additive(s), in accordance with one or more aspects of the present invention; and

FIG. 5 depicts a partial embodiment of a multi-composition fiber with refractory additive(s), in accordance with one or more aspects of the present invention.

### DETAILED DESCRIPTION

Aspects of the present invention and certain features, advantages and details thereof, are explained more fully below with reference to the non-limiting example(s) illustrated in the accompanying drawings. Descriptions of well-known systems, devices, fabrication and processing techniques, etc., are omitted so as to not unnecessarily obscure the invention in detail. It should be understood, however, that the detailed description and the specific example(s), while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure. Note further that numerous inventive aspects and features are disclosed herein, and unless inconsistent, each disclosed aspect or feature is combinable with any other disclosed aspect or feature as desired for a particular application, for instance, for facilitating providing multi-composition fibers with refractory additive(s) and methods of making, as described herein.

Before describing the above-noted aspects further, note that the present invention incorporates or utilizes the following, alone or in any combination, and/or in combination with the subject matter of commonly assigned, International Patent Application No. PCT/US2015/037080, which published on Dec. 30, 2015, as PCT Patent Publication No. WO 2015/200257 A1, and with commonly assigned, U.S. patent application Ser. No. 15/114,504, filed Jul. 27, 2016, entitled: Contiguously Blended Nano-Scaled Multi-Phase Fibers”, which published on Dec. 1, 2016, as U.S. Patent Publication No. 2016/0347672 A1, and with commonly assigned, U.S. patent application Ser. No. 15/320,800, filed Dec. 21, 2016, entitled “An Additive Manufacturing Technology for the Fabrication and Characterization of Nuclear Reactor Fuel”, which published on Jul. 27, 2017, as U.S. Patent Publication No. 2017/0213604 A1, and with commonly assigned, U.S. patent application Ser. No. 15/592,408, filed May 11, 2017, entitled “Fiber Delivery Assembly and Method of Making”, and with commonly assigned, U.S. patent application Ser. No. 15/592,726, filed May 11, 2017, entitled “Multilayer Functional Fiber and Method of Making”, and with commonly assigned, U.S. patent application Ser. No. 15/631,243, filed Jun. 23, 2017, entitled “Nanofiber-Coated Fiber and Methods of Making”, each of which is hereby incorporated herein by reference in its entirety.

Fiber-reinforced composite materials are designed to concomitantly maximize strength and minimize weight. This is achieved by embedding high-strength low-density fibers into a low-density filler matrix in such a way that fibers channel and carry the structural stresses in composite structures. The matrix serves as a glue that holds fibers together and helps transfer loads in shear from fiber to fiber, but in fact the matrix material is not a structural element and carries but a fraction of the overall structural load seen by a composite material.

Composites are thus engineered materials made up of a network of reinforcing fibers—sometimes woven, knitted or braided—held together by a matrix. Fibers are usually packaged as twisted multifilament yarns called “tows”. The matrix gives rise to three self-explanatory classes of composite materials: (1) Polymer Matrix Composites (PMCs), sometimes-called Organic Matrix Composites (OMCs); (2) Metal Matrix Composites (MMC's); and (3) Ceramic Matrix Composites (CMCs).

Such an approach to composite materials in which the tows are but a disorganized bundle of entangled filaments constrains the fibers to a purely structural role. A new approach to the fabrication of multilayered fibers called 1½-D printing allows for the formation of evenly spaced, parallel filaments. Together, this construct constitutes an arbitrary long ribbon of continuous filaments that allow the fiber to break out of their purely structural functions, and enable sweeping new designs in which the fibers contain embedded microsystems. This is described further in the above-referenced, commonly assigned, U.S. patent application Ser. No. 15/592,408.

This approach to fiber manufacturing has been proposed for example as a means to produce TRISO-inspired nuclear fuel embedded within fibers for subsequent embedding into a refractory matrix to form an accident tolerant CMC nuclear fuel, such as described in the above-referenced, commonly assigned PCT Patent Publication No. WO 2015/200257 A1. However, this is but one instance of possible new designs enabled by this technology.

At its core, 1½-D printing rests on the physical principles of Laser Induced Chemical Vapor Deposition to both print continuous filaments and deposit patterns coated onto the fiber. Commonly assigned, U.S. patent application Ser. No. 14/372,085, filed Jul. 14, 2014, entitled “High Strength Ceramic Fibers and Methods of Fabrication”, which published on Jan. 1, 2015, as U.S. Patent Publication No. 2015/0004393 A1, teaches how arrays of filaments can be laser-printed, with diameters potentially varying along their length. The above-referenced, PCT Patent Publication No. WO 2015/200257 A1 teaches how a laser incident to the ribbon can be used to write a pattern of coatings onto a substrate fiber by turning the laser on or off as the ribbon advances. It also teaches that coating thickness can be adjusted. Finally, the above-referenced, commonly assigned U.S. patent application Ser. No. 15/592,408, teaches how such ribbons of parallel filaments can be collected as ribbons onto a tape to enhance fiber volume fraction in the composite.

To implement 1½-D printing, Laser Induced Chemical Vapor Deposition (LCVD) was chosen as the fundamental Additive Manufacturing (AM) tool for its near material independence—an extremely rare property for AM processes. Such a process is said to be “Material Agnostic”. LCVD is a technique derived from CVD, used intensively in the microelectronics fabrication industry (aka “Chip Fab”). CVD builds up electronics-grade high-purity solid deposits from a gas precursor. In its 75+ year history, Chip Fab has accumulated an impressive library of chemical precursors for a wide range of materials, numbering in the 10's of thousands. The main difference between CVD and LCVD resides in dimensionality and mass throughput. CVD is intended for 2-D film growth whereas LCVD is ideally suited for one-dimensional filamentary structures. The dimensionality difference means that deposition mechanisms are greatly enhanced for LCVD vs. CVD, leading to deposited mass fluxes (kg/m2 s) that are 3 to 9 orders of magnitude greater. For example, diamond-like carbon filaments have been measured at linear growth rates upwards of 13 cm/s, which represents a 9 order of magnitude increase in mass flux compared to thin film CVD of the same material. Finally, LCVD is essentially containerless, which virtually eliminates opportunities for material contamination by container or tool.

The following fundamental properties formally defines “1½-D Printing” AM
Material-agnostic ability to grow filaments.
Ability to vary diameter along the length of the filament, as illustrated in FIG. 10 of Pegna et al. (PCT Publication No. WO 2015/200257 A1).
Material-agnostic ability to vary composition along the length of the filament, as was demonstrated by Maxwell et al.
Material-agnostic ability to coat specific sections of filaments with a desired material, morphology and thickness; as illustrated by the nanoporous and other spot coatings shown in FIG. 11 of the above-referenced Pegna et al., PCT publication.

Disclosed herein, in part, is the concept of avoiding the use of polymeric precursors altogether by using laser-assisted chemical vapor deposition (LCVD) as is described in U.S. Pat. No. 5,786,023, entitled “Method and Apparatus for the Freeform Growth of Three-Dimensional Structures Using Pressurized Precursor Flows and Growth Rate Control”, by Maxwell and Pegna, the entirety of which is hereby incorporated by reference herein. In this process pure precursor gases (such as silane and ethylene in the case of SiC fiber production) are introduced into a reactor within which a suitable substrate such as glassy carbon is positioned, and laser light is focused onto the substrate. The heat generated by the focused laser beam breaks down the precursor gases locally, and the atomic species deposit onto the substrate surface and build up locally to form a fiber. If either the laser or the substrate is pulled away from this growth zone at the growth rate a continuous fiber filament will be produced with the very high purity of the starting gases. With this technique there are virtually no unwanted impurities, and in particular no performance-robbing oxygen.

Very pure fibers can be produced using LCVD, such as silicon carbide, boron carbide, silicon nitride and others. The inventors have discovered that if a material has been deposited using CVD, there is a good chance that fiber can be produced using LCVD. Unlike with liquid polymeric precursors, however, where the chemistry can be very involved and complicated even for relatively ‘simple’ materials such as those mentioned above, LCVD can also be used quite directly to produce novel mixes of solid phases of different materials that either cannot be made or have not been attempted using polymeric precursor and spinneret technology. Examples include fibers composed of silicon, carbon and nitrogen contributed by the precursor gases such as silane, ethylene and ammonia, respectively, where the resulting “composite” fiber contains tightly integrated phases of silicon carbide, silicon nitride and silicon carbonitrides depending on the relative concentrations of precursor gases in the reactor. Such new and unique fibers can exhibit very useful properties such as high temperature resistance, high strength and good creep resistance at low relative cost.

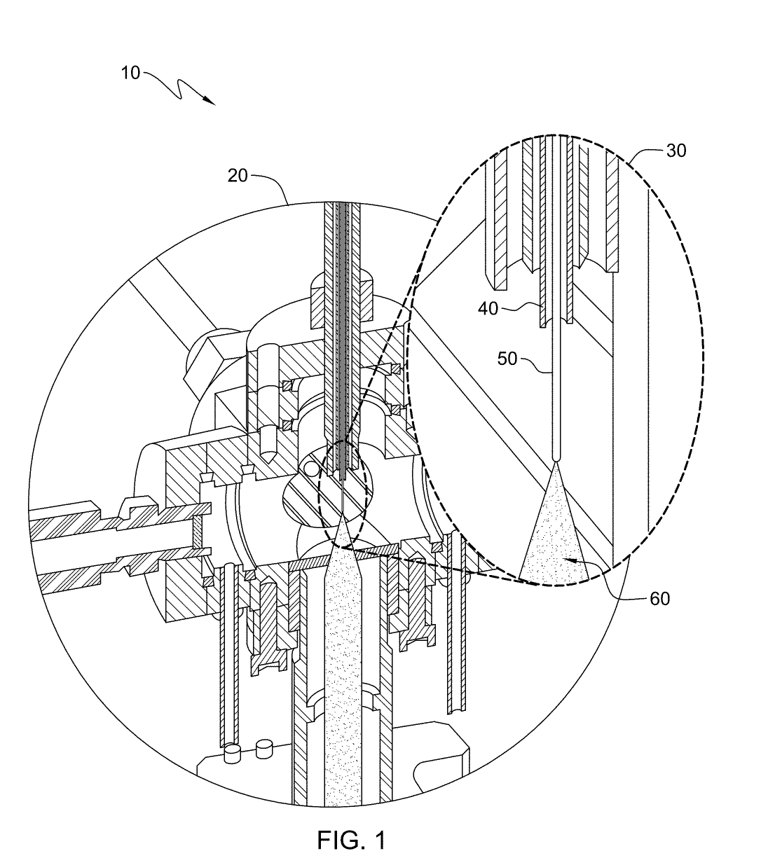

FIG. 1 shows a LCVD reactor into which a substrate seed fiber has been introduced, onto the tip of which a laser beam is focused. (It will be seen that the substrate may be any solid surface capable of being heated by the laser beam. It will further be seen that multiple lasers could be used simultaneously to produce multiple simultaneous fibers as is taught in International Patent Application Serial No. PCT/US2013/022053, which published on Dec. 5, 2013, as PCT Patent Publication No. WO 2013/180764 A1, and in U.S. Patent Publication No. 2015/0004393, the entireties of which are hereby incorporated by reference herein. In accordance with that Application, FIG. 1 more particularly shows a reactor 10; enlarged cutout view of reactor chamber 20; enlarged view of growth region 30. A self-seeded fiber 50 grows towards an oncoming coaxial laser 60 and is extracted through an extrusion microtube 40.

A mixture of precursor gases can be introduced at a desired relative partial pressure ratio and total pressure. The laser is turned on, generating a hot spot on the substrate, causing local precursor breakdown and local CVD growth in the direction of the temperature gradient, typically along the axis of the laser beam. Material will deposit and a fiber will grow, and if the fiber is withdrawn at the growth rate, the hot spot will remain largely stationary and the process can continue indefinitely, resulting in an arbitrarily long CVD-produced fiber.

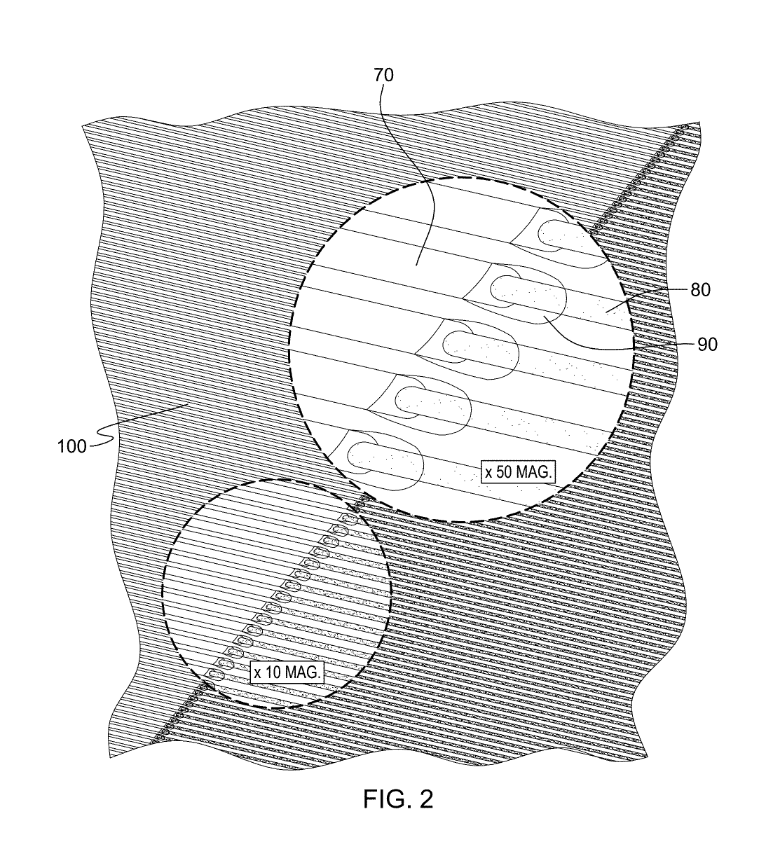

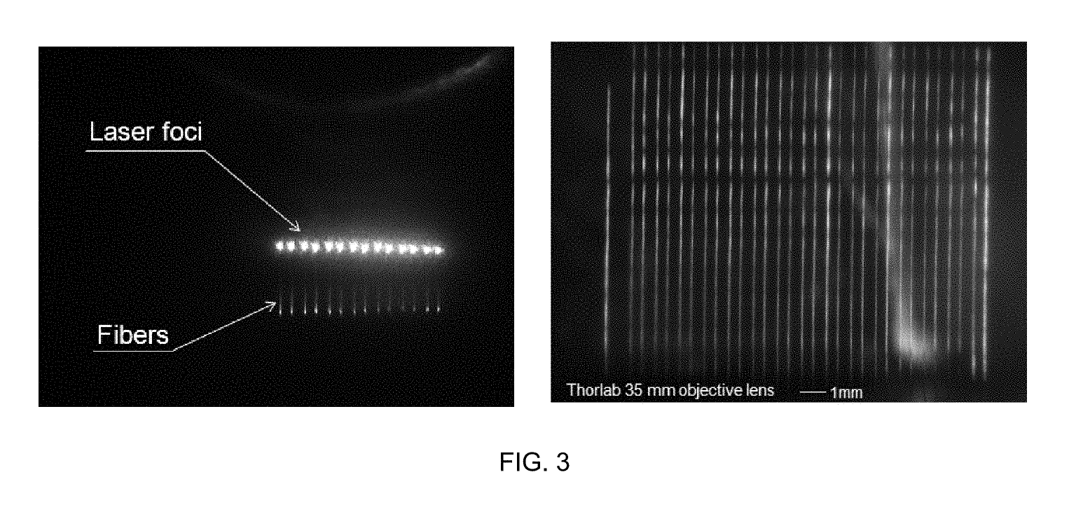

Also in accordance with that Application, a large array of independently controlled lasers can be provided, growing an equally large array of fibers 70 in parallel, as illustrated in FIG. 2, showing how fiber LCVD can be massively parallelized from a filament lattice 100 by multiplication of the laser beams 80 inducing a plasma 90 around the tip of each fiber 70. Using a Computer to Plate (CtP) (e.g., Quantum Well Intermixing (QWI)) laser array for LCVD is a scientific first, and so was the use of a shallow depth of focus. It provides very beneficial results. Sample carbon fibers, such as those shown in FIG. 3, were grown in parallel. FIG. 3 shows parallel LCVD growth of carbon fibers—Left: Fibers during growth and Right: Resulting free standing fibers 10-12 μm in diameter and about 5 mm long.

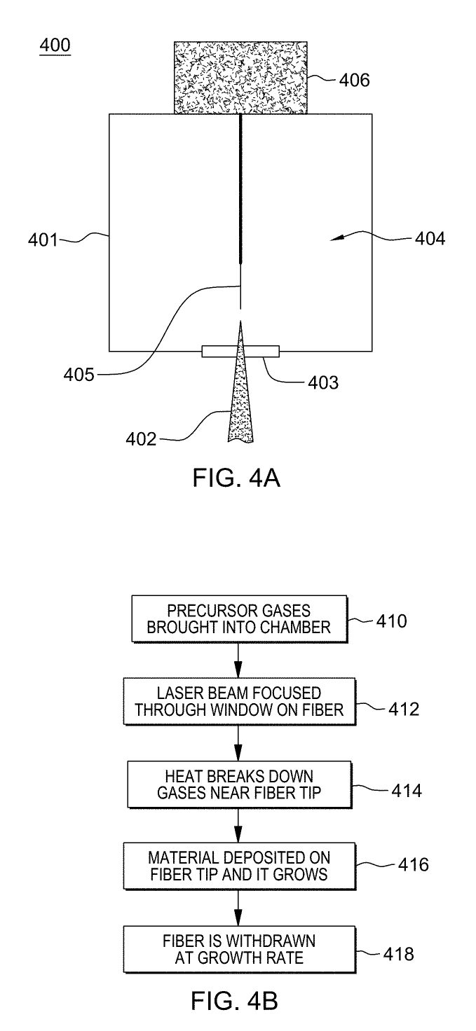

As discussed herein, laser-driven, chemical-vapor deposition (LCVD) technology is capable of forming high-performance ceramic and inorganic fibers for composite material systems. FIG. 1 discussed above is a schematic representation of a monofilament LCVD production process. FIG. 4A is a simplified view of an LCVD production system for producing a multi-composition fiber with one or more refractory additives, in accordance with one or more aspects of the present invention, and FIG. 4B depicts an exemplary process for producing a multi-composition fiber with one or more refractory additives, in accordance with one or more aspects of the present invention.

Referring to FIG. 4A, the LCVD system 400 shown includes a chamber 401 into which one or more lasers 402 are directed through one or more windows 403. Chamber 401 includes precursor gases 404 for facilitating producing a fiber 405 such as disclosed herein. A fiber extraction apparatus 406 facilitates withdrawing the fiber as it is produced within the chamber.

The deposition process may include bringing precursor gases into the chamber 410, as illustrated in FIG. 4B. For a given fabrication process, ratios of the precursor gases are selected and introduced into the chamber. The gases contain the atomic species that are to be deposited in the fiber format. For instance, silicon carbide fibers (SiC) may be formed from silicon-containing and carbon-containing gases, or a single gas that contains both atoms. In addition, a small laser beam is directed into the gas-containing chamber through a window that transmits the laser wavelength 412. This laser beam is focused onto an initiation site, which can be a fiber seed, a thin substrate, or any other solid component that will heat up upon being intersected by the beam and absorb its energy. At this hot spot 414, the precursor gases disassociate and, through certain chemical reaction steps, deposit a desired solid product. For instance, in the example above, the solid SiC deposit accreting together form the fiber 416. The fiber itself grows towards the laser source, and thus the fiber is pulled away and out of the reactor at an equivalent fiber growth rate 418. In this manner, the deposition zone remains at a constant physical position (the focal point of the laser beam), and deposition can continue indefinitely, as long as the laser beam is on and the supply of precursor gases is replenished.

As noted above, FIG. 2 provides a representation of a massive parallelization of the laser beam input, increased from a single beam to a multitude of individually controlled laser beams, to produce high-quality volume array of parallel fibers.

By control of the localized chemistry formed in LCVD-produced fibers, multiple materials may be deposited simultaneously and homogeneously throughout the fiber microstructure. This approach can produce an inorganic, multiple material composite fiber by the LCVD process, which is composed of several desired chemistries.

A noteworthy example for the ceramic matrix composite (CMC) community would entail SiC as the primary fiber and secondarily of refractory-grade materials, such as but not limited to zirconium carbide (ZrC), zirconium diboride (ZrB₂), and hafnium diboride (HfB₂). These refractory compositions are desired in order to improve the overall performance of the SiC fiber in high temperature, oxidizing environments. The attack of oxygen penetrating through the matrix of a CMC component on the reinforcing fiber bundle/array is a significant inhibitor to the lifetime performance of the manufactured material system. The oxidation resistance performance of composite bulk materials containing SiC and additional refractory materials has been reported in the technical literature to be significantly improved over SiC materials without such additions.

A positive feature of using powder-based raw materials is the ability to homogenously mix the various constituent materials, achieving intimate contact between the different ceramic materials. In a similar vein to the powder processing technology, LCVD technology produces an intermixed microstructure when co-depositing dissimilar materials, without creating separate and discrete heterogeneous islands of the constituent materials. This has been achieved in the co-deposition of boron in silicon carbide fibers, in which the boron was well distributed throughout the filament structure (see in this regard, the above-referenced, commonly assigned U.S. Patent Publication No. 2016/0347672 A1). The range of materials available in gas precursors provides the opportunity to utilize LCVD not only to leverage the body of knowledge and literature developed for bulk powder processing, but also with additional material combinations that have been heretofore impossible to fabricate in fiber formats. These concepts include fibers composed of intermixing SiC with ultra-high temperature (UHT, melting/dissociation temperatures greater than 2000° C.) carbides, borides, silicides, and nitrides, such as tantalum and hafnium-based refractories, as well as previously unavailable UHT fiber materials that can be blended with other UHT carbides, borides, nitrides, and silicides for synergistic enhancement of high temperature properties.

An example of such a composite high temperature fiber would be to demonstrate the SiC fiber with ZrC included as a secondary material. The SiC precursors could be any silane-based gas, such as methyltrichlorosilane, to deliver the silicon component while the carbon input could be from a range of hydrocarbons, including methane and propane. There are several zirconium-based metal organic precursors, such as zirconium 2-ethylhexanoate, that have adequate vapor pressure at room temperature to serve as a zirconium source. The precursor gas chemistry would need to be closely regulated to maintain adequate hydrocarbon gas supply and ensure enough carbon is present to attach to both the silicon and zirconium atoms.

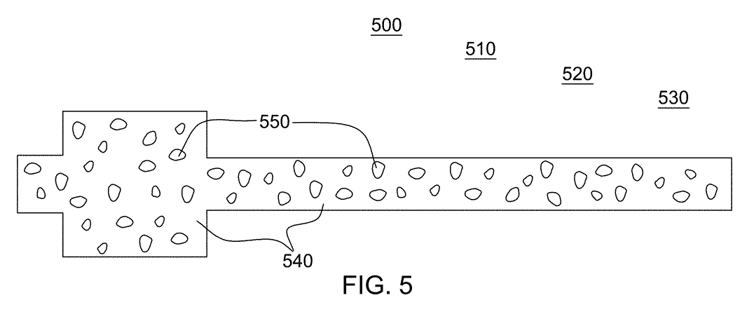

In accordance with one embodiment of the present invention, FIG. 5 illustrates a multi-composition fiber 500 comprising a primary fiber material 540 and a refractory fiber material 550 substantially homogenously intermixed with the primary fiber material 540.

In a more detailed embodiment, primary fiber material 540 comprises silicon carbide, and refractory fiber material 550 comprises zirconium carbide, hafnium carbide, or tantalum carbide.

In an alternative embodiment, primary fiber material 540 comprises silicon carbide, and refractory fiber material 550 comprises zirconium diboride, hafnium diboride, or tantalum diboride.

In another more detailed embodiment, primary fiber material 540 comprises an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. As used herein, an “ordinarily solid material” means a material that is solid at a temperature of 20 degrees Celsius and a pressure of 1 atmosphere.

In another more detailed embodiment, refractory fiber material 550 comprises carbides, or diborides, of titanium, zirconium, hafnium, niobium, tantalum, or tungsten; nitrides of hafnium, tantalum, zirconium, or titanium; oxides of hafnium, zirconium, or magnesium; silicides of zirconium, hafnium, tungsten, or tantalum; or combinations thereof.

In another more detailed embodiment, multi-composition fiber 500 has a substantially non-uniform diameter. For instance, user-directed inputs for the LCVD process growth parameters, such as input laser power and precursor gas characteristics, provide exquisite control over the final formed fiber chemical and physical properties. For instance, these growth parameters can be altered to impart variations in the fiber diameter dimension. In effect, the fiber diameter may be changed from a thinner-to-thicker-to-thinner section (or vice versa), which can be repeated in a desired periodicity or designed in some manner to impart desired physical properties for the fibers in the overall composite performance.

As noted above, another aspect of the present invention, a method of making a multi-composition fiber 500 comprises providing a precursor laden environment 510 and promoting fiber growth using laser heating. Precursor laden environment 510 comprises a primary precursor material 520 and a refractory precursor material 530.

In a more detailed embodiment, precursor laden environment 510 comprises a material selected from a group consisting of gases, liquids, critical fluids, supercritical fluids, and combinations thereof.

In a more detailed embodiment, primary precursor material 520 comprises a precursor for silicon carbide, and refractory precursor material 530 comprises a precursor for zirconium carbide, hafnium carbide, or tantalum carbide.

In an alternative embodiment, primary precursor material 520 comprises a precursor for silicon carbide, and refractory precursor material 530 comprises a precursor for zirconium diboride, hafnium diboride, or tantalum diboride.

In another alternative embodiment, primary precursor material 520 is a precursor for a primary fiber material 540, where primary fiber material 540 comprises an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

In another more detailed embodiment, refractory precursor material 530 is a precursor for a refractory fiber material 550. Refractory fiber material 550 comprises a material selected from a group consisting of: carbides, or diborides, of titanium, zirconium, hafnium, niobium, tantalum, or tungsten; nitrides of hafnium, tantalum, zirconium, or titanium; oxides of hafnium, zirconium, or magnesium; silicides of zirconium, hafnium, tungsten, or tantalum; or combinations thereof.

In another more detailed embodiment, the act of promoting fiber growth using laser heating comprises modulating the laser heating such that multi-composition fiber 100 has a substantially non-uniform diameter.

Those skilled in the art will note from the above description that provided herein are methods of making a multi-composition fiber with refractory additive(s). For instance, the method may include: providing a precursor-laden environment, and promoting fiber growth using laser heating. The precursor-laden environment includes a primary precursor material and a refractory precursor material. In one or more implementations, the precursor-laden environment includes a material selected from a group consisting of gases, liquids, critical fluids, super-critical fluids, and combinations thereof. For instance, the primary precursor material may include a precursor for silicon carbide (SiC), and the refractory precursor material may be a precursor for a material selected from a group consisting of zirconium carbide, hafnium carbide, and tantalum carbide. In another example, the primary precursor material may include a precursor for silicon carbide, and the refractory precursor material may be a precursor for a material selected from a group consisting of zirconium diboride, hafnium diboride, and tantalum diboride.

In one or more implementations, the primary precursor material may be a precursor for a primary fiber material, with the primary fiber material including an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

In one or more embodiments, the refractory precursor material may be a precursor for a refractory fiber material, and the refractory fiber material may include a material selected from a group consisting of: carbides and diborides of a group consisting of titanium, zirconium, hafnium, niobium, tantalum, and tungsten; nitrides of a group consisting of hafnium, tantalum, zirconium, and titanium; oxides of a group consisting of hafnium, zirconium, and magnesium; silicides of a group consisting of zirconium, hafnium, tungsten; and tantalum, and combinations thereof.

In one or more embodiments, the promoting fiber growth using laser heating may include modulating the laser heating such that the multi-composition fiber has a substantially non-uniform diameter.

In one or more embodiments, the precursor material may be a precursor for a primary fiber material, the primary fiber material including an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, the refractory precursor material may be a precursor for a refractory fiber material, where the refractory fiber material includes a material selected from a group consisting of: carbides and diborides of a group consisting of titanium, zirconium, hafnium, niobium, tantalum, and tungsten; nitrides of a group consisting of hafnium, tantalum, zirconium, and titanium; oxides of a group consisting of hafnium, zirconium, and magnesium; silicides of a group consisting of zirconium, hafnium, tungsten, and tantalum; and combinations thereof. In combination with the above method, the precursor-laden environment may include a material consisting of gases, liquids, critical fluids, super-critical fluids, and combinations thereof. Further, the promoting fiber growth using laser heating may include modulating the laser heating such that the multi-composition fiber has a substantially non-uniform diameter.

In one or more further aspects, a multi-composition fiber is disclosed herein which includes a primary fiber material, and a refractory fiber material substantially homogeneously intermixed with the primary fiber material. In one or more embodiments, the primary fiber material includes silicon carbide (SiC), and the refractory fiber material includes a material selected from a group consisting of zirconium carbide, hafnium carbide, and tantalum carbide. In one or more other embodiments, the primary fiber material includes silicon carbide, and the refractory fiber material includes a material selected from a group consisting of zirconium diboride, hafnium diboride, and tantalum diboride.

In one or more embodiments, the primary fiber material may include an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, in one or more embodiments, the refractory fiber material may include material selected from a group consisting of: carbides and diborides of a group consisting of titanium, zirconium, hafnium, niobium, tantalum, and tungsten; nitrides of a group consisting of hafnium, tantalum, zirconium, and titanium; oxides of a group consisting of hafnium, zirconium, and magnesium; silicides of a group consisting of zirconium, hafnium, tungsten, and tantalum; and combinations thereof. Further, in one or more embodiments, the multi-composition fiber may have a substantially non-uniform diameter.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

We claim:

1. A method of making a multi-composition fiber, the method comprising:
providing a precursor laden environment;
promoting fiber growth using laser heating; and
wherein the precursor laden environment comprises a primary precursor material and a refractory precursor material.

2. The method of claim 1, wherein the precursor laden environment comprises a material selected from a group consisting of gases, liquids, critical fluids, supercritical fluids, and combinations thereof.

3. The method of claim 1, wherein the primary precursor material comprises a precursor for silicon carbide, and the refractory precursor material is a precursor for a material selected from a group consisting of zirconium carbide, hafnium carbide, and tantalum carbide.

4. The method of claim 1, wherein the primary precursor material comprises a precursor for silicon carbide, and the refractory precursor material is a precursor for a material selected from a group consisting of zirconium diboride, hafnium diboride, and tantalum diboride.

5. The method of claim 1, wherein the primary precursor material is a precursor for a primary fiber material, the primary fiber material comprising an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

6. The method of claim 1, wherein the refractory precursor material is a precursor for a refractory fiber material, the refractory fiber material comprising a material selected from a group consisting of:
carbides and diborides of a group consisting of titanium, zirconium, hafnium, niobium, tantalum, and tungsten;
nitrides of a group consisting of hafnium, tantalum, zirconium, and titanium;
oxides of a group consisting of hafnium, zirconium, and magnesium;
silicides of a group consisting of zirconium, hafnium, tungsten, and tantalum; and
combinations thereof.

7. The method of claim 1, wherein the promoting fiber growth using laser heating comprises modulating the laser heating such that the multi-composition fiber has a substantially non-uniform diameter.

8. The method of claim 1, wherein the primary precursor material is a precursor for a primary fiber material, the primary fiber material comprising an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof, and the refractory precursor material is a precursor for a refractory fiber material, the refractory fiber material comprising a material selected from a group consisting of:
carbides and diborides of a group consisting of titanium, zirconium, hafnium, niobium, tantalum, and tungsten;
nitrides of a group consisting of hafnium, tantalum, zirconium, and titanium;
oxides of a group consisting of hafnium, zirconium, and magnesium;
silicides of a group consisting of zirconium, hafnium, tungsten, and tantalum; and
combinations thereof.

9. The method of claim 8, wherein the precursor laden environment comprises a material selected from a group consisting of gases, liquids, critical fluids, supercritical fluids, and combinations thereof.

10. The method of claim 8, wherein the promoting fiber growth using laser heating comprises modulating the laser heating such that the multi-composition fiber has a substantially non-uniform diameter.

11. A multi-composition fiber comprising:
a primary fiber material; and
a refractory fiber material substantially homogenously intermixed with the primary fiber material.

12. The multi-composition fiber of claim 11, wherein the primary fiber material comprises silicon carbide, and the refractory fiber material comprises a material selected from a group consisting of zirconium carbide, hafnium carbide, and tantalum carbide.

13. The multi-composition fiber of claim 11, wherein the primary fiber material comprises silicon carbide, and the refractory fiber material comprises a material selected from a group consisting of zirconium diboride, hafnium diboride, and tantalum diboride.

14. The multi-composition fiber of claim 11, wherein the primary fiber material comprises an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

15. The multi-composition fiber of claim 11, wherein the refractory fiber material comprises a material selected from a group consisting of:
carbides and diborides of a group consisting of titanium, zirconium, hafnium, niobium, tantalum, and tungsten;
nitrides of a group consisting of hafnium, tantalum, zirconium, and titanium;
oxides of a group consisting of hafnium, zirconium, and magnesium;
silicides of a group consisting of zirconium, hafnium, tungsten, and tantalum; and
combinations thereof.

16. The multi-composition fiber of claim 11, wherein the multi-composition fiber has a substantially non-uniform diameter.

17. A multi-composition fiber comprising:
a primary fiber material; and
a refractory fiber material; and
wherein:
the primary fiber material comprises an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof, and
the refractory fiber material comprises a material selected from a group consisting of:
carbides and diborides of a group consisting of titanium, zirconium, hafnium, niobium, tantalum, and tungsten;
nitrides of a group consisting of hafnium, tantalum, zirconium, and titanium;
oxides of a group consisting of hafnium, zirconium, and magnesium;
silicides of a group consisting of zirconium, hafnium, tungsten, and tantalum; and
combinations thereof.

18. The multi-composition fiber of claim 17, wherein the multi-composition fiber has a substantially non-uniform diameter.
